(19) United States
(12) Patent Application Publication
(10) Pub. No.: US 2026/0075753 A1
(43) Pub. Date: Mar. 12, 2026

(54) FLUID-COOLED THERMAL SUPPORT STRUCTURE FOR ELECTRONICS DEVICE HAVING ARRAY OF PROJECTIONS WITH NON-UNIFORM ARRANGEMENT

(71) Applicant: Garrett Transportation I Inc., Torrance, CA (US)

(72) Inventors: Alireza Hakimian, Torrance, CA (US); Valeriy Fedorikhin, Hermosa Beach, CA (US); Levon Markossian, Torrance, CA (US)

(73) Assignee: Garrett Transportation I Inc., Torrance, CA (US)

(21) Appl. No.: 18/827,949

(22) Filed: Sep. 9, 2024

(51) Int. Cl. H05K 7/20

(52) U.S. Cl. CPC H05K 7/20254; H05K 7/20927

(57) ABSTRACT

A system for an electronics device includes a thermal support structure with a fluid inlet, a fluid outlet, and an internal coolant passage extending in a downstream direction from the fluid inlet to the fluid outlet. The thermal support structure includes an external support face that supports the electronics device and that is thermally coupled thereto. Furthermore, the thermal support structure includes an internal face that partly defines the internal coolant passage. The internal face includes a plurality of projections that project into the internal coolant passage and that are configured for transfer of heat from the electronics device to a flow of coolant through the internal passage. The plurality of projections is arranged into an array that extends along the downstream direction. A spacing in the array between neighboring ones of the plurality of projections is non-uniform along the downstream direction. The spacing gradually decreases along the downstream direction.

### TECHNICAL FIELD

The present disclosure generally relates to a thermal support structure, such as a cold plate, for an electronics device, and more particularly relates to a fluid-cooled thermal support structure for an electronics device having an array of projections with non-uniform arrangement.

### BACKGROUND

Various electronic devices are provided for a number of operations. For example, a control system for an electric motor system, e-turbomachine (e.g., motorized compressor device, etc.), electric generator, and/or other systems may include electronic devices of various types. These devices may generate heat and/or may be exposed to higher temperatures. Excessive heat may be detrimental to operations of the electronics. Also, non-uniform temperature of the electronics may cause electrical unbalance between different phases of an e-machine, which may negatively affect performance. Therefore, cooling features may be included for maintaining operating temperatures of the electronics within a predetermined range.

However, it may be difficult, expensive, or otherwise challenging to include effective cooling features for an electronics device. If there are a plurality of electronics devices, and they are arranged compactly, these difficulties may be significant.

Thus, it is desirable to provide an improved thermal support structure for an electronics device. It is desirable to provide a structure that provides highly effective cooling within a small and compact package. Moreover, it is desirable to provide a thermal support structure and an electronics package that may be manufactured and assembled in an efficient manner. Other desirable features and characteristics of the present disclosure will become apparent from the subsequent detailed description and the appended claims, taken in conjunction with the accompanying drawings and this background discussion.

### BRIEF SUMMARY

In one embodiment, a system for an electronics device is disclosed. The system includes a thermal support structure with a fluid inlet, a fluid outlet, and an internal coolant passage extending in a downstream direction from the fluid inlet to the fluid outlet. The thermal support structure includes an external support face that supports the electronics device and that is thermally coupled thereto. Furthermore, the thermal support structure includes an internal face that partly defines the internal coolant passage. The internal face includes a plurality of projections that project into the internal coolant passage and that are configured for transfer of heat from the electronics device to a flow of coolant through the internal passage. The plurality of projections is arranged into an array that extends along the downstream direction. A spacing in the array between neighboring ones of the plurality of projections is non-uniform along the downstream direction. The spacing gradually decreases along the downstream direction.

In another embodiment, a method of operating a system for an electronics device is disclosed. The method includes providing an electronics device on a thermal support structure that includes a fluid inlet, a fluid outlet, and an internal coolant passage extending in a downstream direction from the fluid inlet to the fluid outlet. The thermal support structure includes an external support face that supports the electronics device and that is thermally coupled thereto. The thermal support structure includes an internal face that partly defines the internal coolant passage. The internal face includes a plurality of projections that project into the internal passage and that are configured for transfer of heat from the electronics device to a flow of coolant through the internal passage. The plurality of projections is arranged into an array that extends along the downstream direction. A spacing in the array between neighboring ones of the plurality of projections is non-uniform along the downstream direction. The spacing gradually decreases along the downstream direction. The method further includes operating the electronics device and providing the flow of coolant through the internal coolant passage from the fluid inlet to the fluid outlet for receiving heat from the electronics device during operation of the electronics device.

In a further embodiment, an inverter system is disclosed that includes a plurality of transistors. Also, the inverter system includes a thermal support structure with a fluid inlet, a fluid outlet, and an internal coolant passage extending in a downstream direction from the fluid inlet to the fluid outlet. The thermal support structure includes an external support face that supports the plurality of transistors and that is thermally coupled thereto. The thermal support structure includes an internal face that partly defines the internal coolant passage. The internal face includes a plurality of projections that project into the internal coolant passage and that are configured for transfer of heat from the plurality of transistors to a flow of coolant through the internal passage. The plurality of projections are arranged into an array that extends along the downstream direction. A spacing in the array between neighboring ones of the plurality of projections is non-uniform along the downstream direction. The spacing gradually decreases along the downstream direction.

### BRIEF DESCRIPTION OF THE DRAWINGS

The present disclosure will hereinafter be described in conjunction with the following drawing figures, wherein like numerals denote like elements, and wherein:

FIG. 1 is schematic illustration of an electronics system according to example embodiments of the present disclosure;

FIG. 2 is a cross-sectional view of the electronics system, including a thermal support structure, taken along the line 2-2 of FIG. 1;

FIG. 3 is a top view of a first member of the thermal support structure of FIG. 2;

FIG. 4 is a bottom view of a second member of the thermal support structure of FIG. 3;

FIG. 5 is a top view of the first member of the thermal support structure according to additional embodiments of the present disclosure; and

FIG. 6 is a bottom view of the second member of the thermal support structure according to additional embodiments of the present disclosure.

### DETAILED DESCRIPTION

The following detailed description is merely exemplary in nature and is not intended to limit the present disclosure or the application and uses of the present disclosure. Furthermore, there is no intention to be bound by any theory presented in the preceding background or the following detailed description.

Broadly, example embodiments disclosed herein relate to a fluid-cooled thermal support structure, such as a cold plate, for an electronics device. In some embodiments, the thermal support structure may support one or more transistor devices, semiconductors, etc. Furthermore, the thermal support structure of the present disclosure may support and thermally couple to a plurality of MOSFET (metal-oxide semiconductor field-effect transistor) integrated circuits (ICs) of a larger electronic system (e.g., an inverter system).

In some embodiments, the thermal support structure may include a fluid inlet, a fluid outlet, and an internal coolant passage through which a fluid coolant may flow in a downstream direction. The thermal support structure may support and thermally couple to one or more electronics devices (e.g., a MOSFETs) on one face, surface, side, etc. On an opposite face, surface, side, etc., the thermal support structure may include a plurality of projections (e.g., pins, rods, posts, fins, etc.) that project into the internal coolant passage. The coolant may flow through the coolant passage, including flowing across and amongst the plurality of projections. The projections may be included to increase surface area for heat transfer with the fluid coolant. Also, the projections may increase turbulence within the coolant flow for improving heat transfer. As the fluid flows downstream from the inlet to the outlet, heat may be transferred from the electronics devices to the flowing coolant and transferred out from the system for cooling the electronics devices and maintaining the electronics system within predetermined operating temperature ranges.

The plurality of projections may be arranged in an array. The array may extend along the fluid flow path in the downstream direction. The number of projections within a given unit of space of the array (i.e., the “projection density” of the array) may change along the downstream direction. Thus, the “projection density” may vary non-uniformly along the downstream direction. The “projection density” of the array may increase as the array extends further and further along the downstream direction. Accordingly, there may be fewer projections proximate the inlet, and in comparison, there may be more projections proximate the outlet. The “projection density” of the array may gradually increase as the array extends further and further in the downstream direction.

Stated differently, the spacing between neighboring projections may change gradually along the array in the downstream direction. In other words, the array may have non-uniform spacing between the neighboring ones of the plurality of projections. The spacing may decrease as the array extends along the downstream direction. Thus, there may be greater spacing between the projections of the array proximate the inlet (i.e., proximate the inlet end), there may be reduced spacing proximate the outlet (i.e., proximate the outlet end), and the spacing may gradually reduce from the inlet end to the outlet end. The largest spacing between projections (i.e., the lowest projection density) may be found in the area of the flow passage closest to the fluid inlet, and the smallest spacing between the projections (i.e., the highest projection density) may be found in the area of the flow passage closest to the fluid outlet.

Because of this non-uniform arrangement, heat may transfer efficiently from the electronics devices, and the electronics devices may operate substantially at a common temperature. For example, even if the coolant proximate the outlet has been heated by upstream electronics devices, the increased number of projections proximate the outlet may provide increased cooling capacity at the location. Lower projection density proximate the inlet, gradually increasing projection density along the downstream direction, and higher projection density proximate the outlet may accommodate for the increased coolant temperature closer to outlet, thereby maintaining temperatures of the electronics devices within a relatively small, predetermined range. Also, the reduced number of projections proximate the inlet end may provide improved flow and may decrease pressure drop along the coolant passage. Thus, the electronics device(s) supported by the thermal support structure may be maintained substantially at a uniform temperature and may be protected against negative thermal effects. The electronics devices may be more reliable and may operate with greater efficiency. Additionally, the thermal support structure and the electronics system may be highly manufacturable.

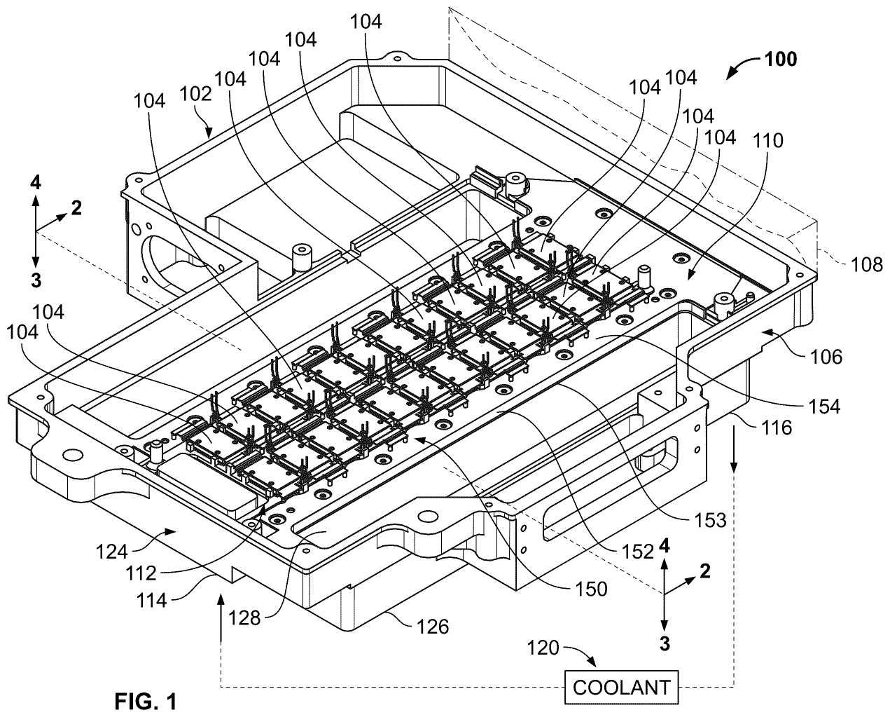

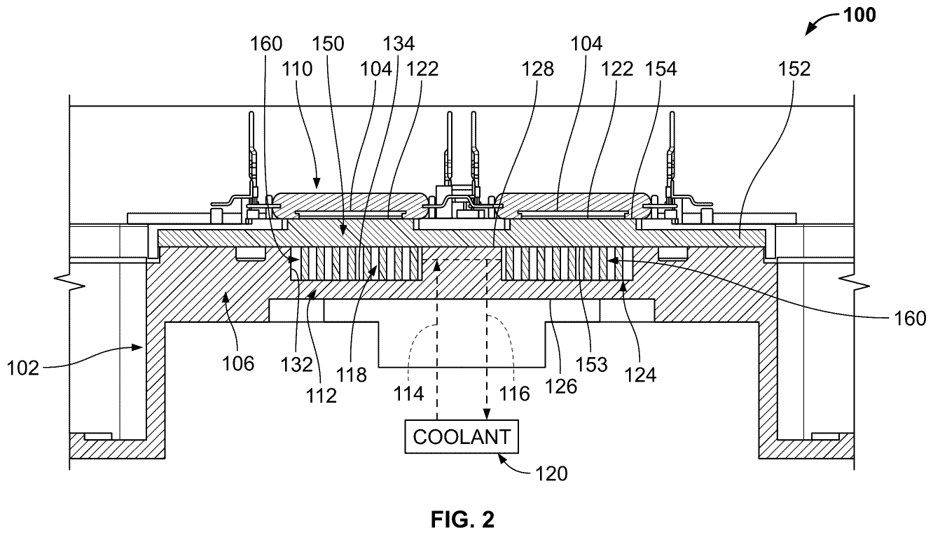

Referring initially to FIGS. 1 and 2, a fluid-cooled electronics system 100 is illustrated according to example embodiments. The electronics system 100 may be of a number of different types without departing from the scope of the present disclosure. In some embodiments, for example, the electronics system 100 may be included within and/or may comprise an inverter system (i.e., a power inverter or frequency inverter) that converts direct current (DC) to alternating current (AC). The electronics system 100 may also be part of a larger system, such as an electric motor system, a turbomachine system, electric generator system, or otherwise.

The system 100 may generally include a housing 102 that houses one or more electronics devices 104. In some embodiments, the electronics devices 104 may be integrated circuit (IC) chips, transistors, etc., such as MOSFETs (metal-oxide semiconductor field-effect transistors). As shown in the embodiment illustrated in FIG. 1, there may be twenty-four (24) MOSFETs arranged in two rows. However, it will be appreciated that there may be any number of electronics devices 104 without departing from the scope of the present disclosure.

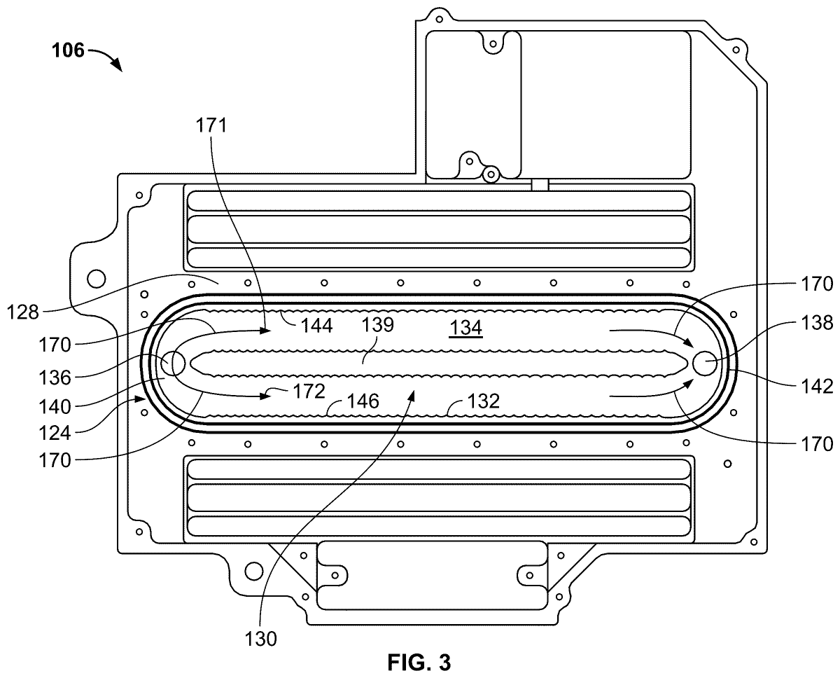

The housing 102 may include a bottom member 106 shown in FIGS. 1 and 2 and shown in isolation in FIG. 3. The housing 102 may also include a top member 108 that is partially shown in phantom in FIG. 1. The top member 108 may be removably attached to the bottom member 106 to define an interior space 110 within the housing 102. The electronics devices 104 may be housed within the space 110.

The system 100 may also include a thermal support structure 112 with a fluid inlet 114, a fluid outlet 116, and an internal coolant passage 118 (FIG. 2) extending therethrough. At least a portion of the thermal support structure 112 may be integrated in and unitary with the bottom member 106 of the housing 102. Furthermore, the electronics devices 104 may be attached to and thermally coupled to the thermal support structure 112 within the housing 102. For example, as shown in FIG. 2, the electronics devices 104 may be mounted atop respective pads 122 on a face of the thermal support structure 112 within the housing 102. The electronics devices 104 may be soldered to the pads 122 to be electrically and mechanically supported on the thermal support structure 112. It will be appreciated that the solder may thermally couple the electronics devices 104 to the thermal support structure 112 such that the thermal support structure 112 may receive heat (i.e., cool) the electronics devices 104.

The thermal support structure 112 may be fluidly coupled to a fluid coolant system 120. The fluid coolant system 120 may be configured for circulating any suitable fluid coolant through the internal coolant passage 118 of the thermal support structure, in a downstream direction from the fluid inlet 114 to the fluid outlet 116. The fluid coolant system 120 may include one or more pipes, lines, or other fluid conduits, as well as a pump, and one or more heat exchangers to define a known cooling cycle.

Accordingly, during operation, heat from the electronics devices 104 may transfer to the thermal support structure 112, and this heat may be further transferred to the coolant flowing through the internal coolant passage 118. Heated coolant may flow out the outlet 116, and fresh coolant may flow in via the inlet 114. The coolant may circulate through the coolant system 120, to cool the electronics devices 104 and maintain operations within a predetermined temperature range.

Referring now to FIGS. 1, 2, and 3, the thermal support structure 112 will be discussed in further detail. In some embodiments, a central portion of the bottom member 106 of the housing 102 may define a portion of the thermal support structure 112. For example, the thermal support structure 112 may include a core housing member 124, and the core housing member 124 may be integrally attached to and unitary with surrounding portions of the bottom member 106 of the housing 102.

The core housing member 124 may include an outer face 126 and an inner face 128. The outer face 126 and/or the inner face 128 may be non-planar. The outer face 126 may face generally outward from the interior space 110 of the housing 102, and the inner face 128 may face generally inward to partly define the interior space 110 of the housing 102. In some embodiments, the bottom member 106 of the housing 102 (and, thus, the core housing member 124) may be made from a metal, such as aluminum alloy, or other material with relatively high thermal conductivity. Also, the bottom member 106 (and, thus, the core housing member 124) may be formed via a forging process or otherwise.

As shown in FIG. 3, the inner face 128 if the core housing member 124 may include a channel 130 that is elongate with a substantially ovoid or elliptical side wall 132 and a bottom surface 134 that is recessed into the inner face 128. In some embodiments, the fluid inlet 114 may include an inlet hole 136 that extends perpendicularly through the bottom surface 134 and/or an outlet hole 138 that extends perpendicularly through the bottom surface 134. The inlet hole 136 and the outlet hole 138 may be disposed at opposite ends of the channel 130 so as to define an inlet end 140 of the channel 130 and an outlet end 142 thereof.

Also, the inner face 128 may include a divider 139, such as thin, wall-like structure that projects from the bottom surface 134. The divider 139 may be elongate and may extend continuously between the inlet end 140 and the outlet end 142. The ends of the divider 139 may be separated at a distance from the side wall 132 at the inlet end 140 and the outlet end 142, respectively. Also, the divider 139 may be substantially centered within the channel 130 so as to be spaced substantially equally from the sides of the side wall 132.

Furthermore, in some embodiments, the side wall 132 may include one or more areas that are non-planar, textured, patterned, arranged with contours, projections, etc. For example, the side wall 132 may include a first side 144 that is contoured and rounded with a sawtooth, ridged, ribbed, or other similar patterned surface feature. Likewise, the side wall 132 may also include an opposite second side 146 that is similarly contoured. In addition, the periphery of the divider 139 may include a similar contoured pattern. It will be appreciated that the bottom surface 134, the side wall 132 (including the contoured first side 144 and second side 146), and the periphery of the divider 139 may each define a boundary surface for fluid flow through the core housing member 124.

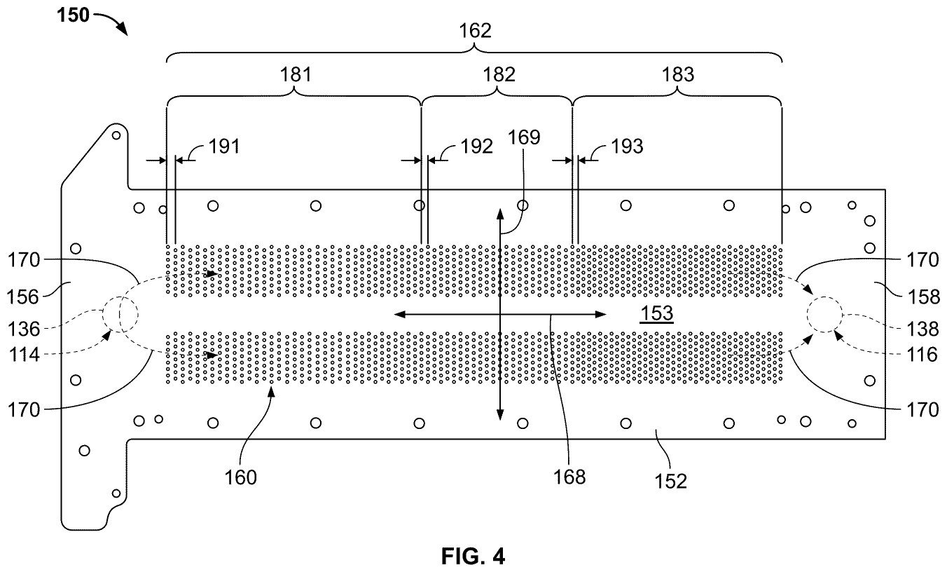

Referring now to FIGS. 1, 2, and 4, additional features of the thermal support structure 112 will be discussed. More specifically, in addition to the core housing member 124 the thermal support structure 112 may include a thermal support member 150, which is shown in isolation in FIG. 4. In some embodiments, the thermal support member 150 may be referred to as a “cold plate.” The thermal support member 150 is discussed below with reference to two orthogonal axes, namely, a first axis 168 and a second axis 169 shown in FIG. 4. The first axis 168 may extend substantially along a downstream direction (indicated by arrows 170), and the second axis 169 may extend perpendicular thereto across the plate member 152.

The thermal support member 150 may be made from a metallic material, such as an aluminum alloy, or other material with high thermal conductivity. The thermal support member 150 may be formed via a forging process or otherwise.

In some embodiments, the thermal support member 150 may include a plate member 152, which is flat and thin. The plate member 152 may be elongate with a first end 156 that is spaced apart from a second end 158. The plate member 152 may be shaped so as to cover over the channel 130 and to attach to the core housing member 124. Accordingly, the plate member 152 may cooperatively define the internal coolant passage 118 with the core housing member 124. More specifically, the plate member 152 may include an internal face 153 and an outer face 154 that are directed in opposite directions. The internal face 153 may face toward the core housing member 124 and may cover over the channel 130, and the outer face 154 may face into the interior space 110 of the housing 102. The pads 122 for supporting the electronics devices 104 may be included on the outer face 154. As shown in FIG. 2, the internal face 153 may partly define the internal coolant passage 118.

Thus, the plate member 152 and the core housing member 124 may cooperatively define the internal coolant passage 118. The internal coolant passage 118 may, thus, be elongate from the inlet 114 to the outlet 116. In other words, the internal coolant passage 118 may have a length measured along the downstream direction 170 (i.e., along the first axis 168), the internal coolant passage 118 may have a width that is measured transverse to the downstream direction (i.e., along the second axis 169), and the length may be greater than the width. The coolant passage 118 may be configured to correspond to the elongated arrangement of the electronics devices 104 for effective cooling thereof.

Additionally, in some embodiments, the internal face 153 may include a plurality of projections 160 that project perpendicularly from the plate member 152. As shown in FIG. 4, the plurality of projections 160 may be provided and arranged in an array 162.

One or more of (e.g., each of) the projections 160 in the array 162 may be pins, rods, or other projections that are attached on one end to the plate member 152 and that extend along a straight projection axis away from the plate member 152. The projections 160 may have a rounded (e.g., circular) cross-section taken normal to the respective projection axis. In some embodiments, the projections 160 may have a cross-section that is common to each of the projections 160. For example, the projections 160 may have substantially the same cross-sectional diameter dimension. Also, in some embodiments, the projections 160 may have substantially the same length. As represented in FIGS. 3 and 4, the projections 160 may be substantially identical, with common dimensions (e.g., same width, length, etc.).

The plurality of projections 160 may cooperatively define the array 162. The array 162 may be elongate and may extend between the first end 156 and the second end 158. In some embodiments, the array 162 may include two straight rows of projections 160 that extend between the first end 156 and the second end 158. The array 162 may be arranged to correspond to the size, volume, and dimensions of the channel 130. As such, when the plate member 152 is attached to the inner face 128 of the core housing member 124, the array 162 of projections 160 may be received and densely arranged within the channel 130. The divider 139 may be received between the two rows of projections 160 within the array 162. The inlet hole 136 and the outlet hole 138 are superimposed on the plate member 152 in FIG. 4 for reference purposes as well. As shown, the array 162 may be provided in the internal coolant passage with both rows of the array 162 extending along the downstream direction 170 from the inlet hole 136 to the outlet hole 138.

Thus, during operation, the fluid coolant system 120 may supply lower-temperature coolant to the inlet 114, and this fluid may flow in the downstream direction 170, amongst the projections 160, and within the spaces between the projections 160, to the outlet 116. The divider 139 may divide the coolant flow supplied to the inlet 114 into a first flow 171 and a second flow 172, and the first flow 171 and second flow 172 may merge further downstream and may outlet together via the outlet 116. The fluid coolant system 120 may circulate coolant through the internal coolant passage 118 for effectively cooling the electronics devices 104. The array of projections 160 increases surface area of exposure for increasing heat exchange and improved cooling capacity. Also, the contoured boundary surfaces provided by the side wall 132 and the divider 139 may increase turbulent flow through the internal coolant passage 118 for further improving cooling capacity of the system 100.

As shown in FIG. 4, the array 162 may be arranged non-uniformly on the plate member 152. The projections 160 in the array 162 may be more densely arranged proximate the outlet 116 as compared to the projections 160 proximate the inlet 114. In other words, the spacing in the array between neighboring ones of the plurality of projections may be greater near the inlet 114 than at the outlet 116. This “projection density” (i.e., the number of projections within a given segment of the internal coolant passage 118) may gradually increase as the array 162 extends from the inlet 114 in the downstream direction 170 toward the outlet 116.

For example, as shown in FIG. 4, the array 162 may include a first zone 181, a second zone 182, and a third zone 183 of projections 160. The first zone 181 may be disposed proximate the inlet 114, the third zone 183 may be disposed proximate the outlet 116, and the second zone 182 may be disposed between the first zone 181 and the third zone 183 in the downstream direction 170. Across the first zone 181, there may be a first projection spacing 191 between neighboring ones of the projections 160 as measured along the first axis 168. Across the second zone 182, there may be second projection spacing 192 between neighboring ones of the projections 160 as measured along the first axis 168. Across the third zone 183, there may be third projection spacing 193 between neighboring ones of the projections 160 as measured along the first axis 168. Thus, the spacing between neighboring projections 160 may be non-uniform and may gradually change along the downstream direction 170. The spacing between neighboring ones of the plurality of projections 160 may gradually decrease along the downstream direction 170 for both the first flow 171 and the second flow 172 of the fluid coolant.

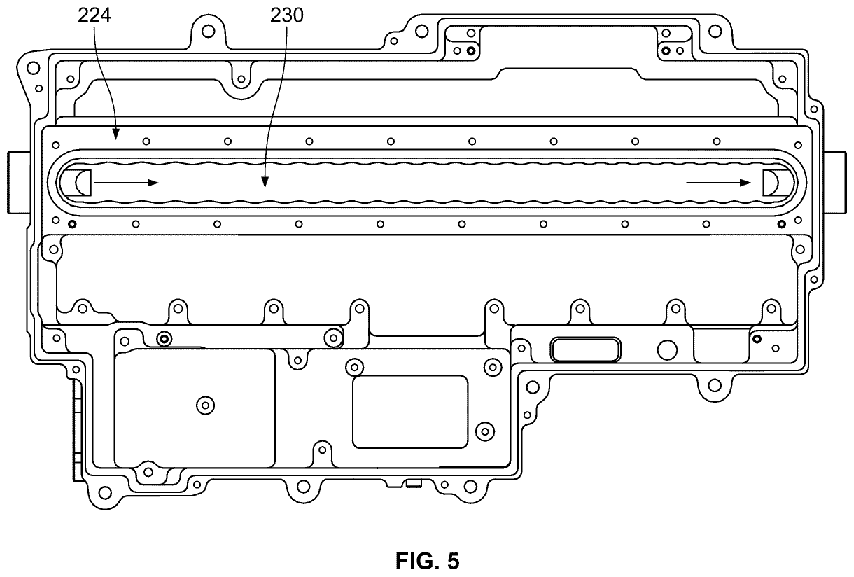

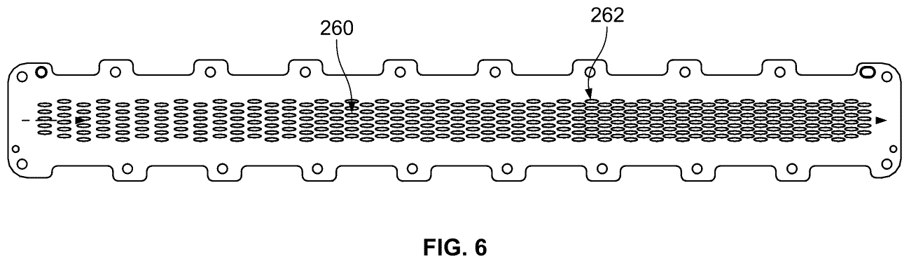

Referring now to FIGS. 5 and 6, additional embodiments are illustrated according to example embodiments. Features that correspond to those of FIGS. 1-4 are indicated with corresponding reference numbers increased by 100.

As shown, the core housing member 224 may include a channel 230 that defines a single flow path (i.e., without a divider) as shown in FIG. 5. Also, as shown in FIG. 6, the projections 260 may have a common, ovate cross-section. The projections 260 may be arranged in the array 262, gradually increasing in density (i.e., gradually decreasing in spacing between projections 260) as the array 262 extends further in the downstream direction.

Because of the non-uniform arrangement of projections 160, 260 within the array 162, 262 heat transfer from the electronics devices 104 may be substantially uniform along the downstream direction 170. The electronics devices 104 may operate substantially at a common temperature. The increased number of projections 160, 260 proximate the outlet 116 may provide increased cooling capacity at the location. Also, the reduced number of projections proximate the inlet 114 may provide improved flow and may decrease pressure drop along the coolant passage 118. Thus, the electronics devices 104 supported by the thermal support structure 150 may be maintained substantially at a uniform temperature and may be protected against negative thermal effects. The electronics devices 104 may be reliable and may operate with high efficiency. Additionally, the thermal support structure 150 and the electronics system 100 may be highly manufacturable.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the present disclosure in any way. Rather, the foregoing detailed description will provide those skilled in the art with a convenient road map for implementing an exemplary embodiment of the present disclosure. It is understood that various changes may be made in the function and arrangement of elements described in an exemplary embodiment without departing from the scope of the present disclosure as set forth in the appended claims.

What is claimed is:

1. A system for an electronics device comprising:
a thermal support structure with a fluid inlet, a fluid outlet, and an internal coolant passage extending in a downstream direction from the fluid inlet to the fluid outlet;
the thermal support structure including an external support face that supports the electronics device and that is thermally coupled thereto; and
the thermal support structure including an internal face that partly defines the internal coolant passage, the internal face including a plurality of projections that project into the internal coolant passage and are configured for transfer of heat from the electronics device to a flow of coolant through the internal passage, the plurality of projections arranged into an array that extends along the downstream direction, a spacing in the array between neighboring ones of the plurality of projections being non-uniform along the downstream direction, the spacing gradually decreasing along the downstream direction.

2. The system of claim 1, wherein individual ones of the plurality of projections extend, respectively, along a projection axis with a cross-section taken normal thereto, the cross-section being common to each of the plurality of projections.

3. The system of claim 2, wherein the cross-section is rounded.

4. The system of claim 3, wherein the cross-section is circular.

5. The system of claim 3, wherein the cross-section is ovate.

6. The system of claim 1, wherein the array has a first zone with a first spacing, a second zone with a second spacing, and a third zone with a third spacing, the second zone disposed between the first zone and the third zone along the downstream direction, the second spacing being greater than the third spacing, and the first spacing being greater than the second spacing.

7. The system of claim 1, wherein the thermal support structure includes a core housing member with a channel recessed thereon; and
wherein the thermal support structure further includes a thermal support member that is fixed to the core housing member and covers over the channel to cooperatively define the internal coolant passage with the core housing member.

8. The system of claim 7, wherein the internal coolant passage is defined by a boundary surface of the core housing member the boundary surface extending along the downstream direction, and wherein the boundary surface is contoured.

9. The system of claim 7, wherein the internal coolant passage is defined by a divider of the core housing member, the divider configured to divide the flow of coolant moving from the fluid inlet to the fluid outlet into a first flow and a second flow.

10. The system of claim 1, wherein the internal coolant passage has a length measured along the downstream direction, wherein the internal coolant passage has a width that is measured transverse to the downstream direction, and wherein the length is greater than the width.

11. A method of operating a system for an electronics device comprising:
providing an electronics device on a thermal support structure that includes a fluid inlet, a fluid outlet, and an internal coolant passage extending in a downstream direction from the fluid inlet to the fluid outlet, the thermal support structure including an external support face that supports the electronics device and that is thermally coupled thereto, and the thermal support structure including an internal face that partly defines the internal coolant passage, the internal face including a plurality of projections that project into the internal passage and are configured for transfer of heat from the electronics device to a flow of coolant through the internal passage, the plurality of projections arranged into an array that extends along the downstream direction, a spacing in the array between neighboring ones of the plurality of projections being non-uniform along the downstream direction, the spacing gradually decreasing along the downstream direction;
operating the electronics device; and
providing the flow of coolant through the internal coolant passage from the fluid inlet to the fluid outlet for receiving heat from the electronics device during operation of the electronics device.

12. The method of claim 11, wherein individual ones of the plurality of projections extend, respectively, along a projection axis with a cross-section taken normal thereto, the cross-section being common to each of the plurality of projections.

13. The method of claim 12, wherein the cross-section is rounded.

14. The method of claim 13, wherein the cross-section is circular.

15. The method of claim 13, wherein the cross-section is ovate.

16. The method of claim 11, wherein the array has a first zone with a first spacing, a second zone with a second spacing, and a third zone with a third spacing, the second zone disposed between the first zone and the third zone along the downstream direction, the second spacing being greater than the third spacing, and the first spacing being greater than the second spacing.

17. The method of claim 11, wherein the thermal support structure includes a core housing member with a channel recessed thereon; and
wherein the thermal support structure includes a thermal support member that is fixed to the core housing member and that covers over the channel to cooperatively define the internal coolant passage with the core housing member.

18. The method of claim 17, wherein the internal coolant passage is defined by a boundary surface of the core housing member the boundary surface extending along the downstream direction, and wherein the boundary surface is contoured.

19. The method of claim 17, wherein the internal coolant passage is defined by a divider of the core housing member, the divider configured to divide the flow of coolant moving from the fluid inlet to the fluid outlet into a first flow and a second flow.

20. An inverter system comprising:
a plurality of transistors; and
a thermal support structure with a fluid inlet, a fluid outlet, and an internal coolant passage extending in a downstream direction from the fluid inlet to the fluid outlet, the thermal support structure including an external support face that supports the plurality of transistors and that is thermally coupled thereto, the thermal support structure including an internal face that partly defines the internal coolant passage, the internal face including a plurality of projections that project into the internal coolant passage and that are configured for transfer of heat from the plurality of transistors to a flow of coolant through the internal passage, the plurality of projections arranged into an array that extends along the downstream direction, a spacing in the array between neighboring ones of the plurality of projections being non-uniform along the downstream direction, the spacing gradually decreasing along the downstream direction.
